(19) United States
(12) Patent Application Publication
(10) Pub. No.: US 2025/0273562 A1
(43) Pub. Date: Aug. 28, 2025

(54) ULTRAFAST TRANSPORT INTERCONNECTS

(71) Applicant: INTERNATIONAL BUSINESS MACHINES CORPORATION, Armonk, NY (US)

(72) Inventors: Atharv Jog, Albany, NY (US); Nicholas Anthony Lanzillo, Wynantskill, NY (US); Daniel Charles Edelstein, White Plains, NY (US); Ching-Tzu Chen, Ossining, NY (US)

(21) Appl. No.: 18/589,913

(22) Filed: Feb. 28, 2024

(51) Int. Cl. H01L 23/522

(52) U.S. Cl. CPC H01L 23/5226

(57) ABSTRACT

A semiconductor device includes a conductive structure. The conductive structure has a primary conductor including a predominantly crystalline material having anisotropic Fermi velocities. A direction of a higher Fermi velocity of the primary conductor is aligned with a direction of electric current flow within the primary conductor.

### BACKGROUND

The present invention generally relates to semiconductor devices and processing methods, and more particularly to interconnects having crystal planes of constituent material oriented to provide enhanced charge transport.

Interconnects in semiconductor devices have a number of methods for formation. In one approach, the interconnects can be formed by depositing a sheet and subtractively etching the sheet to form metal lines. In another approach, a damascene method can be employed where a trench is filled with conductive material to form the interconnects. In both of these approaches, increased resistance to contacting structures, e.g., vias, contacts or other metal structures, can be present. Further, the materials employed for interconnects often include polycrystalline material with isotropic Fermi surfaces, such as, e.g., Cu, Rh, Ir. The isotropic Fermi surfaces can scatter electrons resulting in resistance to electron flow.

The geometry of the materials and the shape of the interconnect can also contribute to impediments to electric current flow. For example, interconnects can suffer from sidewall scattering as well as grain boundary scattering. Side wall scattering occurs when a base material of the interconnect interfaces with other structures, such as, e.g., barrier layers, which are commonly employed before depositing a base material of the interconnect. Grain boundary scattering can occur as the charge traverses grain boundaries of the base material. Even with controlled grain boundaries, transport velocity can be impeded by the orientation of metal interconnect structures.

A need exists for metal interconnect structures that reduce charge scattering and contribute to improved charge transport flow.

### SUMMARY

In accordance with an embodiment of the present invention, a semiconductor device includes a conductive structure. The conductive structure has a primary conductor including a predominantly crystalline material having anisotropic Fermi velocities. A direction of a higher Fermi velocity of the primary conductor is aligned with a direction of electric current flow within the primary conductor.

In other embodiments, the conductive structure can include a templating liner layer. The conductive structure can include a self-assembled molecular monolayer. The conductive structure can include a via and the direction of the higher Fermi velocity can be vertical. The conductive structure can include an interconnect line, and the direction of the higher Fermi velocity can be longitudinal. The predominantly crystalline material can be quasi two-dimensional and include crystal planes of increased Fermi velocity where the crystal planes are parallel to the direction of electric current flow. The predominantly crystalline material can be quasi one-dimensional and can conduct along a crystal direction of the higher Fermi velocity in a direction parallel to the direction of electric current flow.

In accordance with another embodiment of the present invention, a semiconductor device includes a dielectric material having a trench, a liner layer lining the trench and a primary conductor on the liner. The primary conductor has anisotropic Fermi velocities such that a direction of a higher Fermi velocity of the primary conductor is aligned with a direction of electric current flow within the primary conductor.

In other embodiments, a self-assembled molecular monolayer can be disposed between the liner layer and the dielectric material. The primary conductor can include a via and the direction of the higher Fermi velocity can be vertical. The primary conductor can include an interconnect line, and the direction of the higher Fermi velocity can be longitudinal. The primary conductor can include predominantly crystalline material which is quasi two-dimensional and has crystal planes of increased Fermi velocity where the crystal planes are parallel to the direction of electric current flow. The primary conductor can be quasi one-dimensional and can conduct along a crystal direction of the higher Fermi velocity in a direction parallel to the direction of electric current flow.

In accordance with another embodiment of the present invention, a semiconductor device includes a dielectric material having a trench; an interconnect having a primary conductor in the trench; and a via transversely disposed with respect to a longitudinal axis of the interconnect. The via is connected to the interconnect at an interface. The interconnect and the via include predominantly crystalline material having crystal planes of increased Fermi velocity shared between the interconnect and the via through the interface to reduce electrical resistance and charge scattering between the via and the interconnect.

In other embodiments, a templating liner layer lining the trench can be included. A self-assembled molecular monolayer disposed between the templating liner layer and the dielectric material can be included. The crystal planes of increased Fermi velocity can be aligned vertically for the via and along the longitudinal axis of the interconnect. The crystal planes of increased Fermi velocity can be parallel to a direction of electric current flow. The interconnect and the via can include a lamellar structure. A direction of electric current flow can be orthogonal between the via and the interconnect.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor device having a conductive structure with aligned Fermi surfaces where one or more higher Fermi velocities are aligned in a direction of electric current flow, in accordance with an embodiment of the present invention;

FIG. 2 shows a cross-sectional view of a semiconductor device having an interconnect with aligned Fermi surfaces in a direction of electric current flow and having a liner, in accordance with an embodiment of the present invention;

FIG. 3 shows a cross-sectional view of a semiconductor device taken as section line A-A in FIG. 1 showing a direction of electric current flow, in accordance with an embodiment of the present invention;

FIG. 4 shows two cross-sectional views of an interconnect and connecting vias, with one cross-section being taken at section line C-C of the other cross-section, the interconnect and connecting vias sharing Fermi surfaces to permit enhanced electric current flow along the interconnect and transversely in the vias, in accordance with an embodiment of the present invention;

FIG. 5 shows a cross-sectional view of a semiconductor device having an interconnect being annealed to create a predominantly lamellar crystal structure with aligned Fermi surfaces in a direction of electric current flow, in accordance with an embodiment of the present invention;

FIG. 6 shows cross-sectional views of a semiconductor device having a via being annealed to create a predominantly lamellar crystal structure with aligned Fermi surfaces in a direction of electric current flow, in accordance with an embodiment of the present invention; and

FIG. 7 shows a cross-sectional view of a semiconductor device having an inset magnified and showing a conductive structure formed on a templating liner layer, in accordance with an embodiment of the present invention.

### DETAILED DESCRIPTION

In accordance with embodiments of the present invention, devices and methods are described which include forming metal interconnects with textured materials having predominantly favorable crystallographic orientation to improve electric current flow. The electric current flow can be enhanced by reducing charge scatter and increasing permeability of charge through interfaces. In an embodiment, a metal interconnect can include a primary conductor that has one dimensional (1D) or quasi 1D Fermi surfaces or two-dimensional (2D) or quasi 2D Fermi surfaces that can provide fast transport in planes leading to lower line resistance with reduced e-scattering due to geometric features. Quasi 1D refers to flow in predominantly one dimension. Quasi 2D refers to flow a predominant flow in two dimensions. The primary conductor microstructure can improve overall conductance and reduce contact resistance with connected structures or components.

In an embodiment, an interconnect structure can include a predominantly crystalline 2D textured material as a primary conductor where the primary conductor has predominant crystal orientations parallel to a transport direction. In an embodiment, a transport direction can include, e.g., [1000] in materials such as e.g., CoSn, OsRu MoNi₂, VPt₂, a basal plane of PtCoO₂. Other materials can also be employed. Predominantly crystallographic materials refers to materials ranging from perfect, single-crystal materials to materials with polycrystalline or twinning boundaries that still possess crystallographic properties of the single crystal material.

With materials having crystal orientations parallel to the transport direction, electron scattering can be confined to two surfaces (e.g., dominant crystal planes) as opposed to 4 or more surfaces in a conventional conductor. In addition, grain boundary scattering is minimized or eliminated completely by employing predominantly crystalized materials having predominant crystal orientations parallel to the transport direction.

By predominantly orienting crystal planes of the conductive material, a high-conductivity orientation can be achieved. Multiple orientations can be employed with changes in the direction of electric current flow. For example, vias can include crystal planes aligned in a vertical direction (via direction) while interconnects (metal lines) can have crystal planes aligned in a longitudinal direction. Using common planes between structures can further reduce contact resistance at interfaces.

In an embodiment, templating liner layers can be formed prior to the deposition of primary conductor material so that the primary conductor material growth can be facilitated along fast transport directions. Templating liner layers can include, e.g., van der Waal materials, such as, monolayer graphene, multilayer graphene, hexagonal BN, 2D transition-metal dichalcogenides (e.g., MoS₂, WSe₂, MoP₂, TaS₂, TiTe₂), GeTe, SnSe, etc. and their combinations to facilitate growth along a fast transport direction. Self-assembled molecular (SAM) monolayers can be employed to enhance adhesion between low-k dielectrics and van der Waal templating liner layer. SAMs can also inhibit interfacial diffusion and enhance interfacial thermal conductance. Other liners, dielectric sidewall material and even the shape or structure of the channel or trench can be employed to assist in the formation of crystalline textured material in accordance with embodiments of the present invention.

In other embodiments, the conductive structure can include a via and the direction of the higher Fermi velocity can be vertical. The conductive structure can include an interconnect line, and the direction of the higher Fermi velocity can be longitudinal. The predominantly crystalline material can be quasi two-dimensional and include planes of increased Fermi velocity where the planes are parallel to the direction of electric current flow. The predominantly crystalline material can be quasi one-dimensional and can conduct along a crystal direction of the higher Fermi velocity in a direction parallel to the direction of electric current flow.

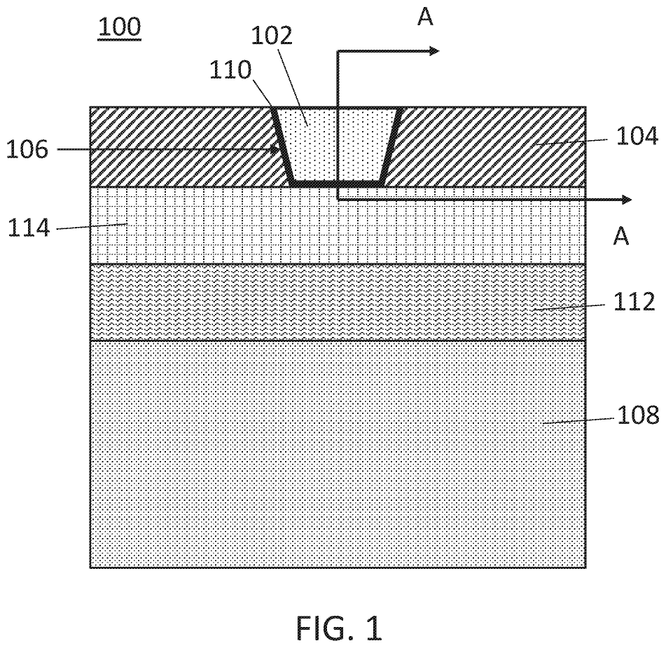

Referring now to the drawings in which like numerals represent the same or similar elements and initially to FIG. 1, devices and methods for manufacturing a semiconductor device 100 are shown in accordance with embodiments of the present invention. The semiconductor device 100 is depicted as a cross-sectional view. The semiconductor device 100 can include any semiconductor device or chip. In particularly useful embodiments, the semiconductor device 100 includes transistors, metal interconnects and other components. In an embodiment, an interconnect line or interconnect 102 is formed by patterning a dielectric layer 104 to form openings or trenches 106 for the formation of metal lines.

The semiconductor device 100 (or semiconductor wafer) can include a substrate 108 that can include a single bulk material or have multiple layers on which the semiconductor device will be fabricated. The substrate 108 can include any suitable substrate structure or material, e.g., a bulk semiconductor, a semiconductor-on-insulator (SOI) substrate, etc., and preferably includes a monocrystalline semiconductor. In one example, the substrate 108 can include substrate portions separated by an etch stop layer (not shown).

Substrate 108 preferably includes silicon-containing material. Illustrative examples of Si-containing materials suitable for the substrate 108 can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

One or more layers are applied to or formed on the substrate 108. These layers can include front end of line (FEOL) components (e.g., source/drain regions, gate structures, etc.) in a FEOL layer 112 and middle end of line (MOL) components (e.g., source/drain contacts, gate contacts, etc.) in an MOL layer 114.

The dielectric layer 104, such as, e.g., an interlevel dielectric layer (ILD) can be formed and can include any suitable material, e.g., selected from the group consisting of silicon containing materials such as SiO₂, Si₃N₄, SiOₓN_{y}, SiC, SiCO, SiCOH, SiCO,N_{y}, SiCOₓN_{y}H, and SiCH compounds, the above-mentioned silicon containing materials with some or all of the Si replaced by Ge, carbon doped oxides, inorganic oxides, inorganic polymers, hybrid polymers, organic polymers, other carbon containing materials, organo-inorganic materials such as spin-on glasses and silsesquioxane-based materials, and diamond-like carbon (DLC), also known as amorphous hydrogenated carbon, (α-C: H).

The dielectric layer 104 can be deposited using chemical vapor deposition (CVD) or plasma-enhanced CVD (PECVD), although other deposition methods can be employed. While the dielectric layer 104 will illustratively be described as being part of a back end of line (BEOL) layer, embodiments of the present invention are not limited to a position within a semiconductor device 100 and can be positioned at any level/layer (e.g., FEOL, MOL, BEOL, far BEOL (FBEOL), frontside or backside of the semiconductor device 100, etc.).

A patterned photoresist can be formed over the semiconductor device 100 by applying a blanket photoresist layer (not shown) to the surface and exposing the photoresist layer to a pattern of radiation, and then developing the pattern into the photoresist layer utilizing resist developer. The pattern in the photoresist layer is transferred to the dielectric layer 104 by an etch process. The trench 106 can be etched into the dielectric layer 104. A planarization process (e.g., CMP) can be employed to level the free surface of the semiconductor device 100. Other patterning techniques can also be employed.

In an embodiment, a liner 110 is formed in the trench 106 prior to formation of a conductor (e.g., primary conductor) for the interconnect 102. In some embodiments, the liner 110 can include one or more layers. For example, the liner 110 can include a diffusion barrier, adhesion layer, a seed layer and/or a templating liner layer. The diffusion barrier, if present, can include, e.g., TiN, TaN, or similar materials. The templating liner layer, if present, can include, e.g., van der Waal materials, such as, monolayer graphene, multilayer graphene, hexagonal BN, 2D transition-metal dichalcogenides (e.g., MoS₂, WSe₂, MoP₂, TaS₂, TiTe₂), GeTe, SnSe, etc. and any combinations of these and other materials. In other embodiments, self-assembled molecular (SAM) monolayers can be employed as part of the liner 110 to enhance adhesion between low-k dielectrics and the templating liner layer.

A conductive fill is performed to form a primary conductor for the interconnect 102, which includes materials for enhancing charge transport therethrough. In embodiments, the primary conductor can include, e.g., CoSn, OsRu MoNi₂, VPt₂, a basal plane of PtCoO₂ or other materials exhibiting an anisotropic charge carrier feature that can support enhanced charge transport when the material is oriented to favor fast transport properties. The primary conductor for the interconnect 102 can include a 1D or 2D Fermi surface(s) or crystal planes that are aligned to enhance electric current flow and reduce scatter. In some embodiments, atomic layer deposition (ALD) or physical vapor deposition techniques can be employed to form the primary conductor of the interconnect 102 (or via or other structures). The 1D or 2D Fermi surface(s) in accordance with crystal directions and/or crystal planes can be oriented to provide improved transport properties of the electric current flow.

Further, treatment, such as an anneal process can be performed to crystallize, further crystallize, or optimize the crystallization or microstructure of the interconnect 102. Processing can continue with further build steps, which can include depositing additional dielectric layers, forming vias, etc. and additional metal structures, as needed.

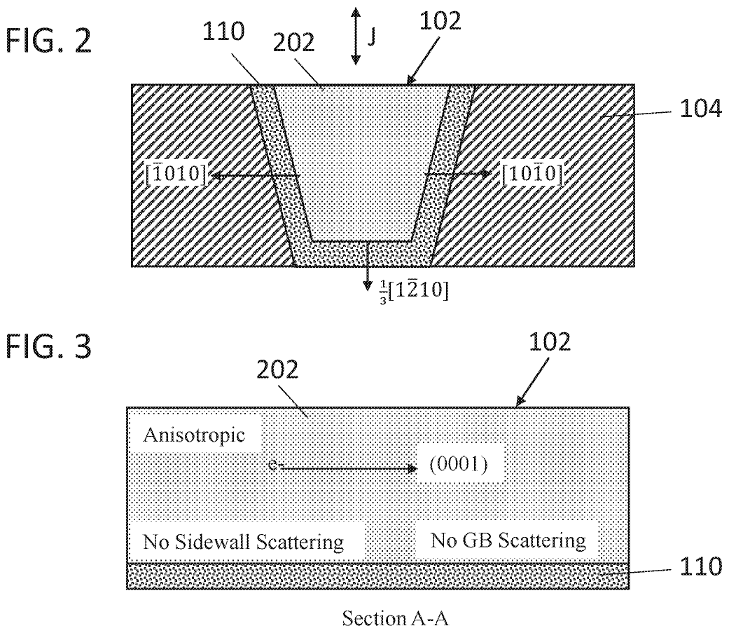

Referring to FIG. 2, a magnified cross-sectional view of the interconnect 102 of FIG. 1 is illustratively depicted. The interconnect 102 includes a primary conductor 202 having a textured structure that promotes enhanced transport characteristics into/out of the plane of the page and vertically in the direction of arrow “J”. In an embodiment, primary conductor 202 can include

CoSn, which interfaces with the liner 110 along planes [1̅010], [101̅0] and ⅓[12̅10]. This results in the alignment of an enhanced transport direction of (0001) into the page and vertically up and down in the direction of arrow “J”.

Referring to FIG. 3 with continued reference to FIG. 2, a cross-sectional view taken at section A-A in FIG. 1 is illustratively depicted in FIG. 3. In section A-A, the interconnect 102 transports charges, in this example an electron along plane (0001). Materials with anisotropic Fermi surfaces can be oriented to favor electric current flow. Anisotropic material of the primary conductor 202 (CoSn, in this example) provides a very large Fermi velocity (V_{f}) along one or more

crystallographic directions (e.g., [0001]). This leads to reduced scattering when the large Fermi velocity is aligned with electron flow. Reduced scattering results in improved overall conductivity as resistance to electron flow is abated.

In accordance with embodiments of the present invention, predominantly crystallographic structuring of the primary conductor 202 creates pathways of enhanced Fermi velocities that favor electric current flow by employing favorable crystallographic directions. This reduces or eliminates sidewall scattering along the interface between the primary conductor 202 and the material that contains the primary conductor 202 (e.g., liner 110 and/or dielectric layer 104). In addition, the predominantly crystallographic structure reduces or eliminates grain boundaries (GB scattering) with the materials of the primary conductor 202. In this way, grain boundary scattering is significantly reduced or eliminated.

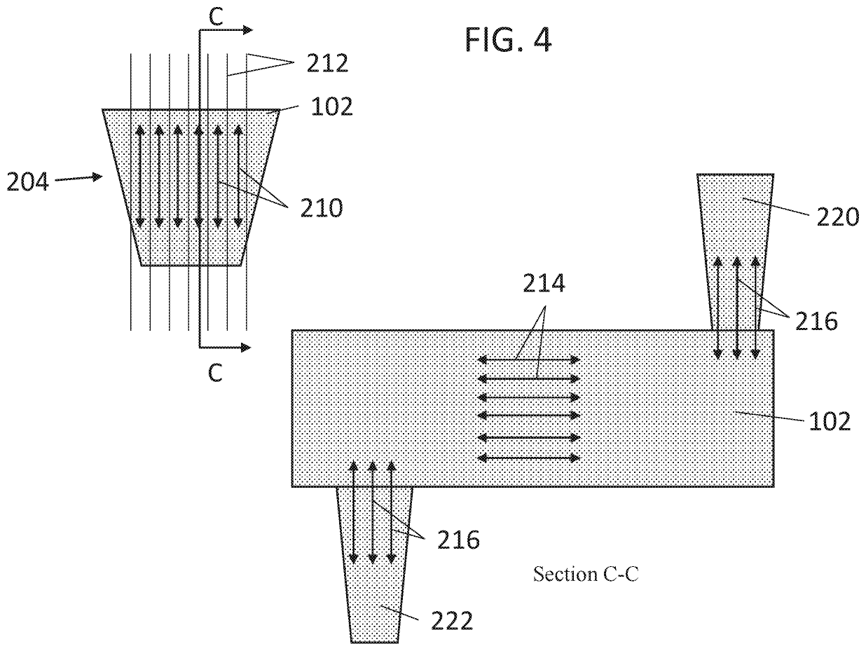

Referring to FIG. 4, a cross-section 204 of the interconnect 102 shows an alignment direction of planes 212 that permit increased Fermi velocity in CoSn. A cross-section C-C taken in between planes 212 at section line C-C in cross-section 204 is also depicted. A zone (arrows 210, 214) of increased Fermi velocity can be disposed between regions of lower Fermi velocity. Said differently, parallel regions alternate between higher and lower regions for Fermi velocity. Regions with arrows 210 permit faster Fermi velocity along a vertical direction and increased Fermi velocity can also be achieved in a direction of arrows 214 in a longitudinal direction of the interconnect 102. The parallel regions can be continued into vias 220 and 222, which can share the same crystal planes. In such a case, vertical flow in the direction of arrows 216 can also be enhanced.

Even if the planes are not completely shared between interconnect 102 and the vias 220, 222 connecting to the interconnect 102, a benefit is still realized by predominantly crystallographic planes of the vias 220, 222 being oriented to favor vertical electric current flow. Sharing planes or merely orienting the planes of the vias 220, 222 vertically permits lower contact resistance with vertical connections such as vias 220, 222. It should be understood that while the example of CoSn is employed, other materials can be employed that have increased Fermi velocity structures that have other shapes and configurations with increased Fermi velocity paths.

Predominantly crystallographic planes can be established by the deposition and annealing techniques employed. In other embodiments, templating liner layers can be employed to assist in aligning crystal planes of the material of the interconnect 102.

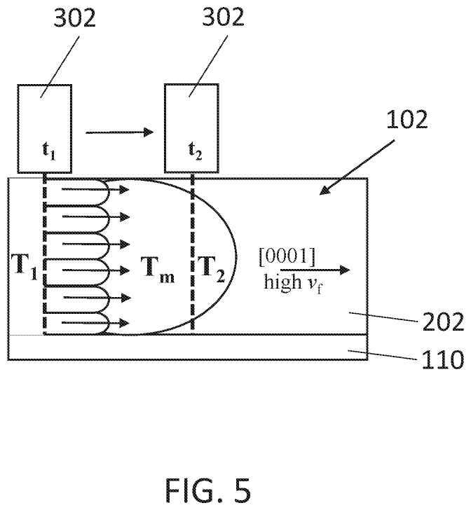

Referring to FIG. 5, a schematic cross-sectional view demonstrates an illustrative technique for creating predominantly crystallographic organization within interconnect 102. The interconnect 102 and in particular, the primary conductor 202 can be subjected to an anneal process. While a global anneal can be performed, a local anneal reserves thermal budget and can be protective of other previously fabricated structures. The material of the primary conductor 202 can initially be polycrystalline in structure and may be annealed to achieve the predominantly crystallographic structure to enhance electric current flow as will be described.

In an embodiment, a surface anneal can be performed. In another embodiment, a laser 302 can be employed to anneal the primary conductor 202. The laser may be continuous-wave (CW), millisecond/microsecond pulsed, or preferably nanosecond-pulsed. In one example, the laser 302 is scanned across the interconnect 102 to anneal the material of the primary conductor 202. As energy is delivered to the primary conductor 202, the temperature is increased from T₁ to T₂. As a beam of the laser 302 moves from its position at time=t₁ to its position at time=t₂, lamellar growth or reorganization occurs within the material of the primary conductor 202 as an intermediary melt temperature T_{M} is achieved (e.g., T₁<T_{M}<T₂). T_{M} represents a temperature where crystallographic growth or organization occurs for the material of the primary conductor 202. A temperature gradient is needed to coax the crystallographic growth. The gradient creates a front that, as it moves, material at the front is melted and at the back solidified into a crystal structure. Crystallographic planes can be assisted by the use of templating liner layers, or crystal seeds can be employed to assist in aligning crystal planes of the material of the interconnect 102. In this and other embodiments, the shape of the container (trench) (e.g., narrow less steep sidewalls) can also be employed as a way of creating crystallographic growth during deposition of the material for the primary conductor 202.

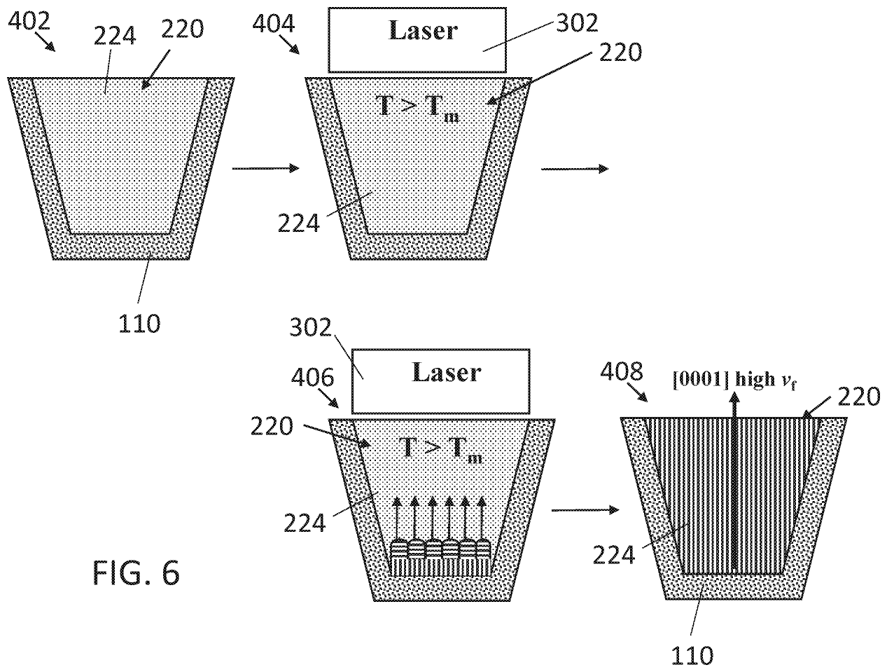

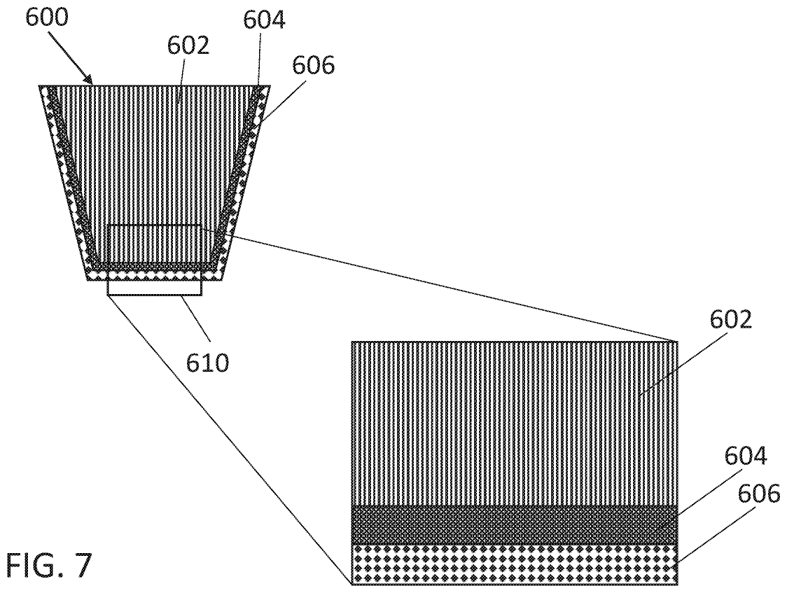

Referring to FIG. 6, schematic cross-sectional views demonstrate an illustrative technique for creating predominantly crystallographic organization within a via 220 (and/or via 222) or other conductive structures. The via 220 and in particular, a primary conductor 224 of the via 220 can be subjected to an anneal process. While a global anneal can be performed, a local anneal reserves thermal budget and can be protective of other previously fabricated structures. At step 402, the material of the primary conductor 224 can initially be polycrystalline in structure and may be annealed to achieve the predominantly crystallographic (minimally polycrystalline) structure to enhance electric current flow as will be described.

In an embodiment, a surface anneal can be performed. In another embodiment, laser 302 can be employed to anneal the primary conductor 202. In one example, in step 404, the laser 302 is directed to a surface of the via 220 to anneal the material of the primary conductor 224. As energy is delivered to the primary conductor 224, the temperature is increased to exceed T_{M}. In step 406, lamellar growth or reorganization occurs within the material of the primary conductor 224 as an intermediary melt temperature T_{M} is achieved. T_{M} represents a temperature where crystallographic growth or organization occurs for the material of the primary conductor 224. A temperature gradient is needed to coax the crystallographic growth. The gradient creates a front that, as it moves, material at the front is melted and at the back solidified into a crystal structure. Crystallographic planes are grown from the bottom up and in the direction of enhanced charge transport. Crystallographic growth can be assisted by the use of templating liner layers or crystal seeds that align crystal planes of the material of the via 220. In this and other embodiments, the shape of the container (trench) (e.g., narrow less steep sidewalls) can also be employed as a way of creating crystallographic growth during deposition of the material for the primary conductor 224.

In step 408, the via 220 include crystal planes for fast transport in a vertical direction. The crystal structure can be grown in the direction in which enhanced transport qualities are desired. It should be noted that instead of or in addition to the use of templating liner layers, crystal structures from other components in contact with the interconnect 102 (FIG. 5) or the via 220 can be employed to seed the crystal structure. For example, a via placed in a previous layer may be employed as a starting point or seed for an interconnect or metal line of a next layer.

Further, templating line layers do not need to be present. In some embodiments, sidewalls of the trench or hole in which the via or line is grown can be employed to initiate crystal growth. This is more practical when steep or vertical sidewalls are present such that epitaxial growth from the sidewalls can occur inwardly towards the center of the via or interconnect line. For example, in some cases, geometry of the trench or via structures can already promote the growth of anisotropic conductors without a template.

Referring to FIG. 7, a conductive structure 600 is shown in cross-section with an inset 610 magnified. The conductive structure 600 can include an interconnect structure, a via structure, a contact structure or any other conductive structure useful in the transport of electrical charge. The conductive structure 600 includes a predominantly crystalline 2D textured material as a primary conductor 602. Predominantly crystalline 2D textured material includes crystal orientations parallel to a charge transport direction (e.g., [0001] in CoSn, basal planes of PtCoOₓ). In such a structure, charge, e.g., electron, scattering is confined to two surfaces, e.g., the parallel planes of the crystal structure. This is in contrast with conventional metal structures which can have four or more scattering surfaces.

Conductive material of the conductive structure 600 has high-conductivity orientations in the direction of electric current flow. These high-conductivity orientations can be achieved by employing alignment layers. An alignment layer can include a seed layer, a seed component (e.g., metal line, via, etc.), a templating liner layer 604 or other alignment materials.

In an embodiment, templating liner layers 604 can be employed to precede the formation of the primary conductor 602. The templating liner layer 604 can include a material such as, e.g., a van der Waals templating material. Examples of templating liner layer 604 can include monolayer graphene, multilayer graphene, hexagonal BN, 2D transition-metal dichalcogenides (e.g., MoS₂, WSe₂, MoP₂, TaS₂, TiTe₂). Other materials for the templating liner layer 604 can include, e.g., GeTe, SnSe, etc. The templating liner layer 604 assists in providing alignment planes upon deposition or anneal of the primary conductor 602. The templating liner layer 604 can be formed using different formation processes depending on the materials employed.

In an embodiment, Self-Assembled Molecular (SAM) monolayers 606 can be used to enhance adhesion to low-k dielectrics (e.g., of an interlevel dielectric layer in which the conductive structure 600 is formed). SAM monolayer 606 can inhibit interfacial diffusion and enhance interfacial thermal conductance at the primary conductor to dielectric interface. Examples of SAM monolayer materials can include 3-mercapto-proply-tri-methoxy-silcane (MPTMS), n-butyltrimethoxysilane (BTMS), etc.

It should be understood that the templating liner layer 604 can be employed without the SAM monolayers 606 and that the primary conductor 602 can be formed without the templating liner layer 604. In some embodiments, a diffusion barrier can be employed prior to depositing the primary conductor 602 or prior to the deposition of the templating liner layer 604. Additional liners or layers can be added or used instead of the layers described.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

Claims:

1. A semiconductor device, comprising:
a conductive structure, the conductive structure having:
a primary conductor including a predominantly crystalline material having anisotropic Fermi velocities wherein a direction of a higher Fermi velocity of the primary conductor is aligned with a direction of electric current flow within the primary conductor.

2. The semiconductor device as recited in claim 1, wherein the conductive structure includes a templating liner layer.

3. The semiconductor device as recited in claim 2, wherein the conductive structure includes a self-assembled molecular monolayer.

4. The semiconductor device as recited in claim 1, wherein the conductive structure includes a via and the direction of the higher Fermi velocity is vertical.

5. The semiconductor device as recited in claim 1, wherein the conductive structure includes an interconnect line and the direction of the higher Fermi velocity is longitudinal.

6. The semiconductor device as recited in claim 1, wherein the predominantly crystalline material is quasi two-dimensional and includes crystal planes of increased Fermi velocity and the crystal planes of increased Fermi velocity are parallel to the direction of electric current flow.

7. The semiconductor device as recited in claim 1, wherein the predominantly crystalline material is quasi one-dimensional and conducts along a crystal direction of the higher Fermi velocity in a direction parallel to the direction of electric current flow.

8. A semiconductor device, comprising:
a dielectric material having a trench;
a liner layer lining the trench; and
a primary conductor on the liner layer and having anisotropic Fermi velocities such that a direction of a higher Fermi velocity of the primary conductor is aligned with a direction of electric current flow within the primary conductor.

9. The semiconductor device as recited in claim 8, further comprising a self-assembled molecular monolayer disposed between the liner layer and the dielectric material.

10. The semiconductor device as recited in claim 8, wherein the primary conductor includes a via and the direction of the higher Fermi velocity is vertical.

11. The semiconductor device as recited in claim 8, wherein the primary conductor includes an interconnect line and the direction of the higher Fermi velocity is longitudinal.

12. The semiconductor device as recited in claim 8, wherein the primary conductor includes predominantly crystalline material which is quasi two-dimensional and has crystal planes of increased Fermi velocity where the crystal planes of increased Fermi velocity are parallel to the direction of electric current flow.

13. The semiconductor device as recited in claim 8, wherein the primary conductor is quasi one-dimensional and conducts along a crystal direction of the higher Fermi velocity in a direction parallel to the direction of electric current flow.

14. A semiconductor device, comprising:
a dielectric material having a trench;
an interconnect having a primary conductor in the trench; and
a via transversely disposed with respect to a longitudinal axis of the interconnect, the via being connected to the interconnect at an interface, the interconnect and the via having predominantly crystalline material having crystal planes of increased Fermi velocity shared between the interconnect and the via through the interface to reduce electrical resistance and charge scattering between the via and the interconnect.

15. The semiconductor device as recited in claim 14, further comprising a templating liner layer lining the trench.

16. The semiconductor device as recited in claim 15, further comprising a self-assembled molecular monolayer disposed between the templating liner layer and the dielectric material.

17. The semiconductor device as recited in claim 14, wherein the crystal planes of increased Fermi velocity are aligned vertically for the via and along the longitudinal axis of the interconnect.

18. The semiconductor device as recited in claim 14, wherein the crystal planes of increased Fermi velocity are parallel to a direction of electric current flow.

19. The semiconductor device as recited in claim 14, wherein the interconnect and the via include a lamellar structure.

20. The semiconductor device as recited in claim 14, wherein a direction of electric current flow is orthogonal between the via and the interconnect.
